(19) United States
(12) Patent Application Publication
(10) Pub. No.: US 2026/0275189 A1
(43) Pub. Date: Sep. 17, 2026

(54) FLUORESCENT BODY POWDER, FLUORESCENT BODY RESIN COMPOSITION, FLUORESCENT BODY, LIGHT-EMITTING ELEMENT, AND LIGHT-EMITTING DEVICE

(71) Applicant: Mitsui Mining & Smelting Co., Ltd., Tokyo (JP)

(72) Inventors: Hiroto KIMURA, Saitama (JP); Daichi KOJIMA, Saitama (JP); Asuka SASAKURA, Saitama (JP)

(21) Appl. No.: 19/469,050

(22) PCT Filed: Feb. 5, 2024
(86) PCT No.: PCT/JP2024/003761

§ 371 Date: Sep. 25, 2025

(30) Foreign Application Priority Data
Mar. 29, 2023 (JP) 2023-053465

(51) Int. Cl. C09K 11/62; C09K 11/77; H10H 20/851

(52) U.S. Cl. CPC C09K 11/625; C09K 11/7703; H10H 20/8512

(57) ABSTRACT

Provided are a phosphor powder exhibiting a high absorbance to blue light, together with a phosphor resin composition, a phosphor, a light-emitting element, and a light-emitting device each containing the phosphor powder.

This phosphor powder has a ratio (I450/I380-420) of fluorescence intensity (I450) with respect to excitation light having a wavelength of 450 nm and maximum fluorescence intensity (I380-420) with respect to excitation light having a wavelength of 380 nm or more and 420 nm or less of 0.88 or more, in an excitation spectrum showing fluorescence intensity of a maximum fluorescence wavelength λmax, provided that the maximum fluorescence wavelength λmax is a fluorescence wavelength that provides maximum fluorescence intensity with respect to an excitation light having a wavelength of 450 nm.

### TECHNICAL FIELD

The present invention relates to a phosphor powder, a phosphor resin composition, a phosphor, a light-emitting element, and a light-emitting device.

### BACKGROUND ART

A light-emitting element in which a light-emitting diode (LED) that emits near-ultraviolet light or blue light is used as a light source (excitation source) and a phosphor is combined with the light-emitting diode is widely used in various light-emitting devices such as a light, a backlight of a mobile terminal, a display, etc.

In these light-emitting devices, the phosphor absorbs light (radiation light) emitted by the LED, and emits light having a wavelength different from that of the absorbed light. Therefore, it is possible to obtain light emission of a color tone different from that of the LED emission light. For example, green light, red light, or white light can be obtained by combining a blue light-emitting LED (blue LED) with a green phosphor and/or a red phosphor.

As a document disclosing an application of a phosphor for an LED, Patent Document 1 discloses a white light-emitting element including a light-emitting diode for emitting blue light, a thiogallate-based green phosphor for emitting green light, and an alkaline earth metal sulfide-based red phosphor for emitting red light, in which the green light and the red light are mixed with a portion of the blue light so as to emit white light (claim 3 of Patent Document 1). In addition, a white light-emitting element is disclosed to be used as a light, a backlight source for notebook computers, or the like (paragraph [0002] of Patent Document 1).

Looking into displays as another application of phosphors, attention has been focused on mini LED displays and micro LED displays recently along with development of display technology. Among them, in a micro LED display, each subpixel—red (R), green (G), and blue (B)—is made up of an independent LED, and is advantageous in that an image having a high luminance and a high contrast ratio can be realized with a high response speed and low power consumption as compared with a liquid crystal panel. In addition, as compared with an organic EL display, there is a feature that an image with high luminance and without burn-in due to property change can be displayed.

Regarding micro LED displays, Patent Document 2 discloses a micro LED display device including a micro LED driving substrate and a micro LED panel (claim 1 of Patent Document 2).

The development of materials of phosphors (phosphor materials) applied to these applications is also ongoing. For example, Patent Document 3 discloses a green light-emitting phosphor represented by the following formula Sr₁₋ₓGa₂S₄:Euₓ (where 0.10≤x≤0.20), which has a maximum emission wavelength of 500 nm or more and 600 nm or less and a half-value width of 46 nm or less (claim 1 of Patent Document 3). In addition, it is disclosed that the green light-emitting phosphor can provide light emission with high color purity and can be applied to a backlight light source for a display device and a light source for lighting ([0008] and [0052] of Patent Document 3).

### CITATION LIST

### Patent Documents

Patent Document 1: Japanese Patent No. 5052507
Patent Document 2: Japanese Unexamined Patent Application, Publication No. 2018-182282
Patent Document 3: Japanese Unexamined Patent Application, Publication No. 2020-139056

### DISCLOSURE OF THE INVENTION

### Problems to be Solved by the Invention

As described above, although the phosphor for LED and the material thereof are used for various applications, it is generally required to have excellent emission color, that is, to suppress mixing of emission colors other than those required. When unrequired colors are mixed, it becomes difficult to obtain a desired color tone and a clear image when the light-emitting device is built up. In order to obtain an excellent emission color, it is important that an emission spectrum (fluorescence spectrum) is narrow and blue light is not transmitted, and for this purpose, a phosphor exhibiting a high absorbance (Abs.) with respect to blue light is desired. Here, the absorbance is a ratio of light absorbed by the phosphor to the irradiated light.

For example, in a phosphor for a micro LED display, as shown in FIG. 1, it is ideal that a phosphor layer composed of a green phosphor and a phosphor layer composed of a red phosphor absorb all of blue light emitted from the LED and excite the phosphor, thereby performing color conversion. Further, the thickness of the phosphor layer is as small as several ten to several hundred μm. Therefore, it is necessary to sufficiently absorb the emitted light (excitation light) even when the phosphor layer is thin, and it is thus particularly important to increase the absorbance of the phosphor.

However, conventional phosphor materials for LED are insufficient to meet this demand.

The present inventors have conducted studies in view of such conventional problems. As a result, in an excitation spectrum of a phosphor powder (powdered phosphor), it has been found that a fluorescence intensity ratio at given wavelengths is related to the absorbance, and the absorbance of blue light can be increased by increasing this fluorescence intensity ratio.

The present invention has been completed based on such finding, and an object of the present invention is to provide a phosphor powder exhibiting a high absorbance to blue light. Another object of the present invention is to provide a phosphor resin composition, a phosphor, a light-emitting element, and a light-emitting device each containing the phosphor powder.

### Means for Solving the Problems

The present invention includes the following aspects (1) to (15). In this description, the expression “to” includes numerical values at both ends thereof. That is, “X to Y” has the same meaning as “X or more and Y or less”.

(1) A phosphor powder having a ratio (I₄₅₀/I₃₈₀₋₄₂₀) of fluorescence intensity (I₄₅₀) with respect to excitation light having a wavelength of 450 nm and maximum fluorescence intensity (I₃₈₀₋₄₂₀) with respect to excitation light having a wavelength of 380 nm or more and 420 nm or less of 0.88 or more,
in an excitation spectrum showing fluorescence intensity of a maximum fluorescence wavelength λmax, provided that the maximum fluorescence wavelength λmax is a fluorescence wavelength that provides maximum fluorescence intensity with respect to an excitation light having a wavelength of 450 nm.
   (2) A phosphor powder having a ratio (I₄₅₀/I₃₃₀₋₃₆₀) of fluorescence intensity (I₄₅₀) with respect to excitation light having a wavelength of 450 nm and maximum fluorescence intensity (I₃₃₀₋₃₆₀) with respect to excitation light having a wavelength of 330 nm or more and 360 nm or less of 0.93 or more,
in an excitation spectrum showing fluorescence intensity of a maximum fluorescence wavelength λmax, provided that the maximum fluorescence wavelength λmax is a fluorescence wavelength that provides maximum fluorescence intensity with respect to an excitation light having a wavelength of 450 nm.
   (3) A phosphor powder having a ratio (I₄₅₀/I₅₀₀) of fluorescence intensity (I₄₅₀) with respect to excitation light having a wavelength of 450 nm and fluorescence intensity (I₅₀₀) with respect to excitation light having a wavelength of 500 nm of 1.4 or more and 2.2 or less,
in an excitation spectrum showing fluorescence intensity of a maximum fluorescence wavelength λmax, provided that the maximum fluorescence wavelength λmax is a fluorescence wavelength that provides maximum fluorescence intensity with respect to an excitation light having a wavelength of 450 nm.
   (4) A phosphor powder having a ratio (I₃₈₀₋₄₂₀/I₂₅₀) of maximum fluorescence intensity (I₃₈₀₋₄₂₀) with respect to excitation light having a wavelength of 380 nm or more and 420 nm or less and fluorescence intensity (I₂₅₀) with respect to excitation light having a wavelength of 250 nm of 2.7 or more,
in an excitation spectrum showing fluorescence intensity of maximum fluorescence wavelength λmax, provided that the maximum fluorescence wavelength λmax is a fluorescence wavelength that provides maximum fluorescence intensity with respect to an excitation light having a wavelength of 450 nm.
   (5) The phosphor powder as described in any one of (1) to (4), in which the phosphor powder includes a crystal of a matrix compound and a light emission center element.
   (6) The phosphor powder as described in (5), in which a concentration ratio of the light emission center element is 8.0 mol % or more and 50 mol % or less.
   (7) The phosphor powder as described in (5) or (6), in which the matrix compound contains a sulfide-based phosphor.
   (8) The phosphor powder as described in any one of (5) to (7), in which the matrix compound contains gallium (Ga), sulfur (S), and at least one metal element selected from the group consisting of barium (Ba), strontium (Sr), and calcium (Ca).
   (9) The phosphor powder as described in any one of (5) to (8), in which the matrix compound has a basic composition of (Ba,Sr)Ga₂S₄.
   (10) The phosphor powder as described in any one of (1) to (9), in which the phosphor powder has a composition represented by (Ba,Sr)₁₋ₓGa₂S₄:Euₓ (where 0.08≤x≤0.50).
   (11) The phosphor powder as described in any one of (1) to (10), in which the phosphor powder has an absorbance of 65% or more with respect to excitation light having a wavelength of 450 nm.
   (12) A phosphor resin composition including the phosphor powder as described in any one of (1) to (11) and a resin.
   (13) A phosphor including the phosphor resin composition as described in (12).
   (14) A light-emitting element including the phosphor as described in (13) and an excitation source.
   (15) A light-emitting device including the light-emitting element as described in (14).

### Effects of the Invention

According to the present invention, a phosphor powder exhibiting a high absorbance to blue light is provided. According to the present invention, a phosphor resin composition, a phosphor, a light-emitting element, and a light-emitting device each containing the phosphor powder are provided.

### BRIEF DESCRIPTION OF THE DRAWINGS

FIG. 1 is a diagram for explaining a phosphor for a micro LED display;

FIG. 2 is a graph showing excitation spectra of phosphor powders of Examples 1 to 3;

FIG. 3 is a graph showing excitation spectra of phosphor powders of Examples 4 to 6;

FIG. 4 is a graph showing excitation spectra of phosphor powders of Examples 7 and 8;

FIG. 5 is a graph showing excitation spectra of phosphor powders of Comparative Examples 1 to 3.

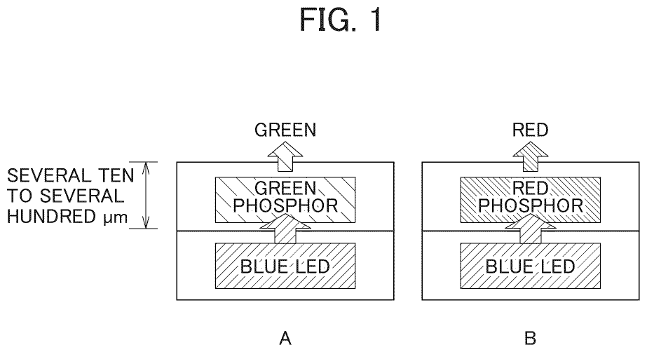

### PREFERRED MODE FOR CARRYING OUT THE INVENTION

A specific embodiment of the present invention (hereinafter referred to as “the present embodiment”) is described. The present invention is not limited to the following embodiments, and various modifications can be made without departing from the scope of the present invention.

### «1. Phosphor Powder»

The phosphor powder of the present embodiment includes any one or more of the following first to fourth aspects.

### <First Aspect>

In the phosphor powder according to the first aspect, the ratio (I₄₅₀/I₃₈₀₋₄₂₀) of the fluorescence intensity (I₄₅₀) with respect to the excitation light having a wavelength of 450 nm and maximum fluorescence intensity (I₃₈₀₋₄₂₀) with respect to excitation light having a wavelength of 380 nm or more and 420 nm or less is 0.88 or more in an excitation spectrum showing fluorescence intensity of a maximum fluorescence wavelength λmax. Here, the maximum fluorescence wavelength λmax is a fluorescence wavelength that provides maximum fluorescence intensity with respect to excitation light having a wavelength of 450 nm. That is, in an excitation spectrum showing fluorescence intensity of the maximum fluorescence wavelength λmax, the ratio (I₄₅₀/I₃₈₀₋₄₂₀) of fluorescence intensity (I₄₅₀) with respect to excitation light having a wavelength of 450 nm and maximum fluorescence intensity (I₃₈₀₋₄₂₀) with respect to excitation light having a wavelength of 380 nm or more and 420 nm or less is 0.88 or more, where the maximum fluorescence wavelength λmax is a fluorescence wavelength that provides maximum fluorescence intensity in an emission spectrum (fluorescence spectrum) measured with excitation light having a wavelength of 450 nm.

By increasing the fluorescence intensity ratio (I₄₅₀/I₃₈₀₋₄₂₀), the absorbance of blue light is increased, and as a result, transmission of blue light can be suppressed. The reason for this is inferred as follows: while a plurality of energy levels exist in a light emission center element (Eu²⁺ or the like) in a matrix material crystal, the abundance of ⁷F₃ state located at the energy level of 450 nm is increased to be higher than those of ⁷F₆ or ⁷F₅ state, which increases the absorbance of blue light. The reason why the fluorescence intensity ratio (I₄₅₀/I₃₈₀₋₄₂₀) with respect to excitation light having a wavelength of 450 nm is used as an index is that the emission wavelength of a blue LED, which is most frequently used as an excitation source of an LED phosphor, is 450 nm.

In addition, by increasing the fluorescence intensity ratio (I₄₅₀/I₃₈₀₋₄₂₀), it is possible to increase a degree of freedom in designing a light-emitting element. That is, in addition to an LED having an emission wavelength of 450 nm, an LED having an emission wavelength of around 460 nm may be used as an excitation source of the phosphor. By increasing the fluorescence intensity ratio (I₄₅₀/I₃₈₀₋₄₂₀), a stable fluorescence intensity with respect to the excitation light wavelength can be obtained. Therefore, a degree of freedom in selecting the excitation wavelength and the excitation source is increased. From the viewpoint of enhancing not only the absorbance of blue light but also the degree of freedom in designing the light-emitting element, the fluorescence intensity ratio (I₄₅₀/I₃₈₀₋₄₂₀) is preferably 0.90 or more, and more preferably 0.91 or more. The upper limit of the fluorescence intensity ratio (I₄₅₀/I₃₈₀₋₄₂₀) is 1.00. That is, the fluorescence intensity ratio (I₄₅₀/I₃₈₀₋₄₂₀) is preferably 0.88 or more and 1.00 or less, and more preferably 0.91 or more and 1.00 or less.

The fluorescence intensity ratio (I₄₅₀/I₃₈₀₋₄₂₀) can be obtained by the following procedure. First, a phosphor powder is analyzed using a spectrofluorometer to obtain a fluorescence spectrum (emission spectrum; PL spectrum). The fluorescence spectrum is a spectrum of fluorescence intensities obtained by fixing the excitation light wavelength to a specific value and scanning the fluorescence wavelength. By examining the fluorescence spectrum, it is possible to investigate which wavelength is the strongest in the light emitted by the phosphor. Then, in the obtained fluorescence spectrum, a wavelength (maximum fluorescence wavelength λmax) that provides the maximum fluorescence intensity is obtained. In a phosphor powder emitting green light (green phosphor powder), λmax is typically in the range of 490 nm or more and 550 nm or less (for example, 535 nm).

Then, the phosphor powder is analyzed using a spectrofluorometer to obtain an excitation spectrum (PLE spectrum). The excitation spectrum is a spectrum of fluorescence intensities obtained by fixing the fluorescence wavelength (emission wavelength emitted from the phosphor) to a specific value and scanning the wavelength of excitation light incident on the phosphor. By examining the excitation spectrum, it is possible to confirm at which wavelength the fluorescence is emitted most strongly, that is, the optimum excitation wavelength. In the present embodiment, the excitation spectrum is obtained by fixing the fluorescence wavelength to the maximum fluorescence wavelength λmax.

Thereafter, in the obtained excitation spectrum, the maximum fluorescence intensity (I₃₈₀₋₄₂₀) with respect to excitation light having a wavelength in the range of 380 nm to 420 nm and the fluorescence intensity (I₄₅₀) with respect to excitation light having a wavelength of 450 nm are obtained. Here, the maximum fluorescence intensity (I₃₈₀₋₄₂₀) is maximum fluorescence intensity in the range of the excitation light wavelength of 380 nm or more and 420 nm or less. The fluorescence intensity (I₄₅₀) is the fluorescence intensity when the excitation light wavelength is 450 nm. Then, the fluorescence intensity ratio (I₄₅₀/I₃₈₀₋₄₂₀) is calculated from the obtained I₃₈₀₋₄₂₀ and I₄₅₀.

### <Second Aspect>

In the phosphor powder according to the second aspect, a ratio (I₄₅₀/I₃₃₀₋₃₆₀) of the fluorescence intensity (I₄₅₀) with respect to excitation light having a wavelength of 450 nm and the maximum fluorescence intensity (I₃₃₀₋₃₆₀) with respect to excitation light having a wavelength of 330 nm or more and 360 nm or less is 0.93 or more in an excitation spectrum showing fluorescence intensity of a maximum fluorescence wavelength λmax. Here, the maximum fluorescence wavelength λmax is as described in the first aspect. The maximum fluorescence intensity (I₃₃₀₋₃₆₀) is the maximum fluorescence intensity in the range of the excitation light wavelength of 330 nm or more and 360 nm or less. That is, in an excitation spectrum showing fluorescence intensity of the maximum fluorescence wavelength λmax, the ratio (I₄₅₀/I₃₃₀₋₃₆₀) of fluorescence intensity (I₄₅₀) with respect to excitation light having a wavelength of 450 nm and maximum fluorescence intensity (I₃₃₀₋₃₆₀) with respect to excitation light having a wavelength of 330 nm or more and 360 nm or less is 0.93 or more, where the maximum fluorescence wavelength λmax is a fluorescence wavelength that provides maximum fluorescence intensity in an emission spectrum (fluorescence spectrum) measured with excitation light having a wavelength of 450 nm.

By increasing the fluorescence intensity ratio (I₄₅₀/I₃₃₀₋₃₆₀), the absorbance of blue light is further increased. The reason for this is inferred as follows: while a plurality of orbits exist as 5d orbits in the light emission center element (Eu²⁺ or the like) in a matrix material crystal, the absorbance of blue light can be more satisfactorily increased by increasing the abundance of 5_{d\hat{ }2}, which influences the fluorescence intensity (I₄₅₀), rather than increasing the abundance of 5d_{xy} or 5d_{x\hat{ }2-y\hat{ }2}, which particularly influences the maximum fluorescence intensity (I₃₃₀₋₃₆₀). From the viewpoint of increasing the absorbance, the fluorescence intensity ratio (I₄₅₀/I₃₃₀₋₃₆₀) is more preferably 0.95 or more, and still more preferably 0.96 or more. Incidentally, the upper limit of the fluorescence intensity ratio (I₄₅₀/I₃₃₀₋₃₆₀) is preferably 2.00. That is, the fluorescence intensity ratio (I₄₅₀/I₃₃₀₋₃₆₀) is preferably 0.93 or more and 2.00 or less, more preferably 0.95 or more and 2.00 or less, and further preferably 0.96 or more and 2.00 or less.

### <Third Aspect>

In the phosphor powder according to the third aspect, the ratio (I₄₅₀/I₅₀₀) of the fluorescence intensity (I₄₅₀) with respect to excitation light having a wavelength of 450 nm and the fluorescence intensity (I₅₀₀) with respect to excitation light having a wavelength of 500 nm is 1.4 or more and 2.2 or less in an excitation spectrum showing fluorescence intensity of a maximum fluorescence wavelength λmax. Here, the maximum fluorescence wavelength λmax is as described in the first aspect. That is, in an excitation spectrum showing fluorescence intensity of the maximum fluorescence wavelength λmax, the ratio (I₄₅₀/I₅₀₀) of fluorescence intensity (I₄₅₀) with respect to excitation light having a wavelength of 450 nm and fluorescence intensity (I₅₀₀) with respect to excitation light having a wavelength of 500 nm is 1.4 or more and 2.2 or less, where the maximum fluorescence wavelength λmax is a fluorescence wavelength that provides maximum fluorescence intensity in an emission spectrum (fluorescence spectrum) measured with excitation light having a wavelength of 450 nm.

By limiting the fluorescence intensity ratio (I₄₅₀/I₅₀₀) within the above-described range, the absorbance of blue light is further increased. The reason for this is that the wavelength of 500 nm is in a region where the emission wavelength of a green phosphor overlaps. That is, when the absorbance with respect to this wavelength (500 nm) becomes high, the light converted by the phosphor is reabsorbed, which lowers the light-emitting performance. Therefore, it is presumed that the excitation intensity of 500 nm needs to be appropriately low with respect to 450 nm. From the viewpoint of increasing the absorbance, the fluorescence intensity ratio (I₄₅₀/I₅₀₀) is more preferably 1.6 or more and 2.0 or less.

### <Fourth Aspect>

In the phosphor powder according to the fourth aspect, the fluorescence ratio (I₃₈₀₋₄₂₀/I₂₅₀) of the maximum fluorescence intensity (I₃₈₀₋₄₂₀) with respect to excitation light having a wavelength of 380 nm or more and 420 nm or less and the fluorescence intensity (I₂₅₀) with respect to excitation light having a wavelength of 250 nm is 2.7 or more in an excitation spectrum showing fluorescence intensity of a maximum fluorescence wavelength λmax. Here, the maximum fluorescence wavelength λmax is as described in the first aspect. That is, in an excitation spectrum showing fluorescence intensity of the maximum fluorescence wavelength λmax, the ratio (I₃₈₀₋₄₂₀/I₂₅₀) of maximum fluorescence intensity (I₃₈₀₋₄₂₀) with respect to excitation light having a wavelength of 380 nm or more and 420 nm or less and fluorescence intensity with respect to excitation light having a wavelength of 250 nm is 2.7 or more, where the maximum fluorescence wavelength λmax is a fluorescence wavelength that provides maximum fluorescence intensity in an emission spectrum (fluorescence spectrum) measured with excitation light having a wavelength of 450 nm.

By limiting the fluorescence intensity ratio (I₂₃₀₋₄₂₀/I₂₅₀) within the above-described range, the absorbance of blue light is further increased. The reason for this is considered as follows: the region of 250 nm corresponds to an excitation band of the matrix compound, and the higher the concentration of the light emission center element (such as Eu²⁺) in the matrix compound, the lower the existence probability of the matrix compound to be excited. From the viewpoint of increasing the absorbance, the fluorescence intensity ratio (I₃₈₀₋₄₂₀/I₂₅₀) is more preferably 2.8 or more, and still more preferably 2.9 or more. The upper limit of the fluorescence intensity ratio (I₃₈₀₋₄₂₀/I₂₅₀) is not limited. However, it is typically 5.0 or less. That is, the fluorescence intensity ratio (I₃₈₀₋₄₂₀/I₂₅₀) is preferably 2.7 or more and 5.0 or less, more preferably 2.8 or more and 5.0 or less, and still more preferably 2.9 or more and 5.0 or less.

The phosphor powder of the present embodiment satisfies at least one of the requirements defined in the first to fourth aspects described above. That is, only one of the requirements may be satisfied, or two or more of the requirements may be satisfied, or all of the requirements may be satisfied. When any two or more of the requirements are satisfied, any two or more of the first to fourth aspects may be combined and satisfied.

A material composition of the phosphor powder of the present embodiment is not limited as long as the phosphor powder exhibits fluorescent properties. The phosphor powder is composed of a phosphor material, and generally contains crystals of a matrix compound and a light emission center element (activator). As the phosphor material, oxide-based, sulfide-based, oxysulfide-based, nitride-based, and oxynitride-based materials are known, and any of them may be used.

For example, as the oxide-based phosphor material, (Y,Gd,Lu)₃(Al,Ga)₅O₁₂:Ce³⁺, (Ba,Sr,Ca)₂SiO₄:Eu²⁺, (Ba,Sr,Ca)₃MgSi₂O₈:Eu²⁺, CaAl₁₂O₁₉:Mn⁴⁺, Ca₃Sc₂Si₃O₁₂:Ce³⁺, CaSc₂O₄:Ce³⁺, (Ba,Sr)₃SiO₅:Eu²⁺, Li₂SrSiO₄:Eu²⁺, Ba₉Sc₂Si₆O₂₄:Eu²⁺, Ca₃Si₂O₇:Eu²⁺, LiSrPO₄:Eu²⁺, CaLa₄Si₃O₁₃:Eu³⁺, Ba₂Gd₃Li₃Mo₈O₃₂:Eu³⁺, BaMgAl₁₀O₁₇:Eu²⁺,Mn²⁺, etc.

Examples of the sulfide-based phosphor material include (Ba,Sr,Ca)Ga₂S₄:Eu²⁺, (Ba,Sr,Ca)Ga₂S₄:Ce³⁺, (Sr,Ca)S:Eu²⁺, (Sr,Cd)S:Eu²⁺, ZnS:Cu, etc.

Examples of the oxysulfide-based phosphor material include (La,Y)₂O₂S:Eu³⁺, La(Ca,Sr)Ga₃S₆O:Eu²⁺, etc.

Examples of the nitride-based phosphor material include (Ba,Sr,Ca)₂Si₅N₈:Eu²⁺, (Ba,Ca,Sr)AlSiN₃:Eu²⁺, La₃Si₆N₁₁:Ce³⁺, (Ba,Sr,Ca)LiAl₃N₄:Eu²⁺, Sr(Mg₃SiN₄):Eu²⁺, (Ba,Sr)₂Si₅N₈:Eu²⁺, etc.

Examples of the oxynitride phosphor material include Eu-containing α-type sialon, Eu-containing β-type sialon, Ba₉Sc₃Si₆O₂₁N₃:Eu²⁺, Ba₃Si₆O₁₂N₂:Eu²⁺, BaSi₂O₂N₂:Eu²⁺, (Ba,Sr,Ca)AlSi(ON)₃:Eu²⁺, etc.

Examples of other phosphor materials include Sr₁₀(PO₄)₆C₁₂:Eu²⁺, K₂(Si,Ge,Ti)F₆:Mn⁴⁺, etc.

According to a preferred aspect, the phosphor powder contains: a matrix compound containing gallium (Ga), sulfur (S), and at least one metal element selected from the group consisting of barium (Ba), strontium (Sr), and calcium (Ca); and a light emission center element, as described in the compositions listed above as the sulfide-based phosphor material. More preferably, the matrix compound has a basic composition of (Ba,Sr)Ga₂S₄. Preferably, the light emission center element includes at least one element selected from the group consisting of europium (Eu), cerium (Ce), manganese (Mn), and samarium (Sm). From the viewpoint of increasing internal quantum efficiency (IQE) upon excitation by blue light generated from the LED, the light emission center element preferably contains Eu, more preferably contains a divalent ion (Eu²⁺) of Eu, and still more preferably contains only Eu²⁺.

The content of the light emission center element in the phosphor powder is not limited on the assumption that the phosphor powder satisfies the requirements of the fluorescence intensity ratio defined in the first to fourth aspects described above. However, from the viewpoint of more reliably and easily satisfying the above-described requirements, it is preferable that the light emission center element is incorporated in the phosphor powder to form a solid solution at a high concentration. A high fluorescence intensity ratio (I₄₅₀/I₃₈₀₋₄₂₀, etc.) and high absorbance can be achieved by incorporating the light emission center element to form a solid solution at a high concentration. Regardless of the composition of the phosphor powder, the concentration ratio of the light emission center element is preferably 8.0 mol % or more and 50 mol % or less. Here, the concentration ratio of the light emission center element is a ratio (XA/(XM+XA)) of the molar amount (XA) of the light emission center element to the sum of the molar amount (XM) of the matrix compound and the molar amount (XA) of the light emission center element contained in the phosphor powder. The higher the concentration ratio of the light emission center element, the higher the ratio (I₄₅₀/I₃₈₀₋₄₂₀), and as a result, the absorbance of blue light becomes high. From the viewpoint of enhancing the absorbance, the concentration ratio is preferably 12 mol % or more, and more preferably 13 mol % or more. On the other hand, when the concentration ratio is excessively high, the light emission center element cannot completely be incorporated in the matrix compound to form a solid solution and a heterophase may be formed. Formation of the heterophase may cause problems such as a decrease in emission intensity. From the viewpoint of suppression of heterophase formation, the concentration ratio is preferably 45 mol % or less, and more preferably 40 mol % or less. From the viewpoint of enhancing the absorbance while suppressing heterophase formation, the concentration ratio is preferably 12 mol % or more and 45 mol % or less, and more preferably 13 mol % or more and 40 mol % or less.

According to a preferred aspect, the phosphor powder has a composition represented by (Ba,Sr)₁₋ₓGa₂S₄:Euₓ (where 0.08≤x≤0.50). This phosphor powder contains a thiogallate-based compound as the matrix compound and europium (Eu) as the light emission center element, and exhibits green light-emission by excitation light having a wavelength ranging from the near ultraviolet region to the blue region (about 300 nm to 510 nm). In addition, since the phosphor contains the light emission center element (Eu) at a relatively high concentration, the phosphor can exhibit a high absorbance with respect to blue light. From the viewpoint of enhancing the absorbance, an Eu amount x is preferably 0.12 or more, and more preferably 0.13 or more. From the viewpoint of suppressing heterophase formation, x is preferably 0.45 or less, and more preferably 0.40 or less. From the viewpoint of enhancing the absorbance while suppressing the heterophase formation, the Eu amount x is preferably 0.12 or more and 0.45 or less, and more preferably 0.13 or more and 0.40 or less.

According to a further preferred aspect, the phosphor powder has a composition represented by (Ba_{y}Sr_{1-y})₁₋ₓGa_{z}S₄:Euₓ (where 0.08≤x≤0.50, 0.00≤y≤1.00, and 1.5≤z≤2.5). Since this phosphor powder contains the light emission center element (Eu) at a relatively high concentration, the phosphor powder can exhibit a high absorbance with respect to blue light. From the viewpoint of enhancing the absorbance, the Eu amount x is preferably 0.12 or more, and more preferably 0.13 or more. In light of suppressing heterophase formation, x is preferably 0.45 or less, and more preferably 0.40 or less. From the viewpoint of enhancing the absorbance, a Ba amount y is preferably 0.50 or less, and more preferably 0.30 or less. From the viewpoint of suppressing heterophase formation, a Ga amount z is preferably 1.7 or more and 2.3 or less.

The phosphor powder may or may not include a coating layer. By providing a coating layer, durability such as moisture resistance can be improved. From the viewpoint of improving durability and maintaining good luminous properties of the phosphor, the coating layer is preferably made of one or more inorganic compounds such as silicon dioxide (SiO₂), zinc oxide (ZnO), aluminum oxide (Al₂O₃), titanium oxide (TiO₂), and/or an oxide containing boron (B), or a metal sulfate such as barium sulfate (BaSO₄), etc.

The phosphor powder may contain a component other than the phosphor material. Examples of such a component include a flux component such as a sintering aid added at the time of synthesizing the phosphor powder.

The phosphor powder of the present embodiment has a high fluorescence intensity ratio of any one or more of the above-described first to fourth aspects, and therefore has a high absorbance of blue light. As a result, the emission spectrum (fluorescence spectrum) is narrow, and an excellent emission color is exhibited. From the viewpoint of obtaining more excellent emission color, the higher the absorbance with respect to excitation light having a wavelength of 450 nm, the more preferable. Specifically, the absorbance is preferably 65% or more, more preferably 69% or more, and still more preferably 75% or more. The upper limit of the absorbance is not limited. It may be 100% or less. However, in some applications such as lighting and mini LED displays, it may not be necessary to increase the absorbance to 100%. In such a case, the absorbance may be 95% or less. The absorbance is preferably 65% or more and 100% or less, more preferably 69% or more and 100% or less, and still more preferably 75% or more and 95% or less.

### «2. Method for Producing Phosphor Powder»

The manufacturing method of the phosphor powder of the present embodiment is not limited on the assumption that the above-described requirements are satisfied. However, it is preferable that the phosphor powder of the present embodiment is manufactured by a method where the light emission center element is incorporated in the matrix compound to form a solid solution at a high concentration, the crystallinity of the matrix compound is increased, and strain is reduced. A specific preferable manufacturing method includes a step of preparing a raw material mixture by mixing raw materials (raw material mixing step) and a step of sintering the obtained raw material mixture (sintering step). In addition, from the viewpoint of easily realizing promotion of incorporation of the light emission center element to form a solid solution and improvement in the crystallinity of the matrix compound, it is preferable to lower (retard) the temperature rising rate during sintering the raw material mixture and to raise the sintering temperature to some extent. A preferable manufacturing method is described in detail below by taking, as an example, a case where the phosphor powder has a composition represented by (Ba,Sr)₁₋ₓGa₂S₄:Euₓ (where 0.08≤x≤0.50).

### <Raw Material Mixing Step>

In the raw material mixing step, raw materials are mixed to prepare a raw material mixture. When the phosphor powder has a composition represented by (Ba,Sr)₁₋ₓGa₂S₄:Euₓ, a barium (Ba) raw material, a strontium (Sr) raw material, a gallium (Ga) raw material, a europium (Eu) raw material, and, if necessary, a sulfur (S) raw material are weighed and mixed. The mixing ratio of the raw materials may be adjusted so that the composition of the finally obtained phosphor powder is (Ba,Sr)₁₋ₓGa₂S₄:Euₓ (where 0.08≤x≤0.50). The raw materials may include only one constituent element among elements (constituent elements) constituting the phosphor powder, or may include a combination of a plurality of constituent elements. When a solid component is used as the sulfur raw material, the sulfur raw material may be mixed. When a gas component is used as the sulfur raw material, the sulfur raw material may not be mixed.

Examples of the barium raw material and the strontium raw material include oxides, sulfides, complex oxides, and/or carbonates of the respective elements. Examples of the gallium raw material include oxides (Ga₂O₃, GaO). Examples of the sulfur raw material include strontium sulfide (SrS), barium sulfide (BaS), sulfur (S), silicon sulfide (SiS₂), cerium sulfide (Ce₂S₃), and/or hydrogen sulfide (H₂S) gas. Examples of the europium raw material include europium fluoride (EuF₃), europium oxide (Eu₂O₃), and/or europium chloride (EuCl₃).

A rare earth element such as praseodymium (Pr) or samarium (Sm) may be added to the raw material in order to adjust the emission wavelength of the phosphor powder or to improve external quantum efficiency (EQE). In order to improve excitation efficiency, at least one element selected from rare earth elements such as scandium (Sc), lanthanum (La), gadolinium (Gd), or lutetium (Lu) may be added to the raw material as a sensitizer. However, the addition amount of each of these is preferably 5 mol % or less with respect to strontium (Sr). When the content of these elements is 5 mol % or less, precipitation of a large amount of a heterophase can be prevented, and a significant decrease in luminance can be prevented. In addition, a monovalent cation such as an alkali metal element, a silver ion (Ag⁺), or the like, or an ion of halogen such as chlorine (Cl), fluorine (F), iodine (I), or the like may be added to the raw material as a electrical charge compensating agent. From the viewpoints of electrical charge compensation effect and luminance, it is preferable that the amount of addition is about equal to the content of the aluminum group element or rare earth element.

A method of mixing raw materials is not limited. Either a dry method or a wet method may be used. In the case of dry mixing, for example, by using zirconia balls as media, the mixture is mixed in a mixer such as a paint shaker or a ball mill, and the mixture is dried as necessary to prepare a raw material mixture. In the case of wet mixing, for example, the following method may be used: a solvent such as water is added to raw materials to form a suspension; the suspension is agitated in a mixer such as a paint shaker or a ball mill, using zirconia balls as media; then, the media is separated using a sieve or the like, and the solvent is removed from the suspension by a drying method such as reduced-pressure drying or vacuum drying.

Next, the obtained raw material mixture is sintered to prepare a sintered product. If necessary, prior to sintering, the raw material mixture may or may not be subjected to grinding, classification and/or drying.

In addition, from the viewpoint of promotion of incorporation of the light emission center element (Eu²⁺, etc.) to form a solid solution and improvement in the crystallinity of the matrix compound, it is preferable to lower the temperature rising rate during sintering the raw material mixture and to raise the sintering temperature to some extent. When the temperature rising rate is too high or the sintering temperature is too low, the dissolution of the light emission center element does not proceed, and there is a possibility that a heterophase remains in the finally obtained phosphor powder. In addition, the crystallinity of the matrix compound is lowered, and strain may remain. On the other hand, when the temperature rising rate is excessively low or the sintering temperature is excessively high, the time required for the process becomes long, and there is a possibility that productivity is lowered. In addition, the constituent elements in the raw material mixture may volatilize to cause a composition deviation of the phosphor powder. The temperature rising rate is preferably 0.05° C./min or more and 5° C./min or less, and more preferably 0.1° C./min or more and 0.4° C./min or less. The sintering temperature is preferably 900° C. or higher and 1200° C. or lower, and more preferably 1050° C. or higher and 1150° C. or lower. The sintering retention time is preferably 24 hours or more and 168 hours or less.

As the sintering atmosphere, an inert gas, a reducing gas, or the like can be employed. Examples of the atmosphere include an argon atmosphere, a nitrogen atmosphere, a sulfur atmosphere, a hydrogen gas-containing argon atmosphere, a hydrogen gas-containing nitrogen atmosphere, and a hydrogen sulfide atmosphere. Among them, sintering in a hydrogen sulfide atmosphere is preferable.

When the raw material mixture includes a sulfur (S) raw material, sintering can be performed under an atmosphere of hydrogen sulfide, carbon disulfide, or an inert gas. When hydrogen sulfide or carbon disulfide is used, the hydrogen sulfide or carbon disulfide forms a sulfur compound during the sintering, and has an effect of suppressing decomposition of a product. On the other hand, when the raw material does not contain a sulfur raw material, it is preferable to sinter in a sulfur-containing atmosphere such as hydrogen sulfide or carbon disulfide.

Next, the sintered product is crushed into powder. Crushing may be performed by either a dry method or a wet method. In the case of the wet method, ethanol, water, or the like can be used as a dispersion medium. The crushing may be performed using a known crusher such as a ball mill, a stamp mill, a jet mill, an automatic mortar grinder, and/or a paint shaker. If necessary, the crushed product obtained by crushing may be subjected to classification treatment. When classification is performed, the particle diameter of the product is crushed to be preferably 0.01 μm or more and 150 μm or less, and more preferably 1 μm or more and 50 μm or less, from the viewpoint of enhancing handleability and luminous properties of the obtained phosphor. Here, the particle diameter refers to a particle diameter (D50) at a cumulative volume of 50% by volume measured by a laser diffraction scattering particle size distribution measuring method. Thus, the phosphor powder of the present embodiment can be obtained.

### «3. Phosphor Resin Composition»

The phosphor resin composition of the present embodiment includes the phosphor powder described above and a resin. The phosphor resin composition is a phosphor paste as a precursor of the phosphor. A phosphor is prepared by applying or shaping the phosphor resin composition.

As the resin, for example, one or more selected from a thermoplastic resin, a thermosetting resin, an ionizing radiation curable resin, or a two-component mixture curable resin can be used. Examples of the thermoplastic resin include polyolefin-based resins such as polyethylene, polypropylene, etc.; polyester-based resins such as polyethylene terephthalate, polybutylene terephthalate, etc.; a polycarbonate resin; polyacrylic acid-based resins such as polyacrylic acid or ester thereof, polymethacrylic acid or ester thereof, etc.; polyvinyl-based resins such as polystyrene, polyvinyl chloride, etc.; cellulose-based resins such as triacetyl cellulose, etc.; urethane resins such as polyurethane, etc., or the like. Examples of the thermosetting resin include a silicone resin, a phenol resin, an epoxy resin, a melamine resin, a urea resin, an unsaturated polyester resin, an alkyd resin, a polyurethane resin, a polyimide resin, etc. Examples of the ionizing radiation curable resin include an acrylic resin, a urethane resin, a vinyl ester resin, a polyester alkyd resin, etc. These resins can be used as not only a polymer but also as an oligomer or a monomer. An example of the two-component mixture curable resin is an epoxy resin.

An amount of the phosphor powder contained in the phosphor resin composition is preferably 5 parts by mass or more, and more preferably 20 parts by mass or more with respect to 100 parts by mass of the resin from the viewpoint of easily securing the absorbance while obtaining a sufficient external quantum efficiency. On the other hand, from the viewpoint of securing suitable formability (fillability), the amount is preferably 100 parts by mass or less, and more preferably 70 parts by mass or less, with respect to 100 parts by mass of the resin.

The phosphor resin composition may contain an organic solvent, an additive, or the like. The viscosity of the phosphor resin composition (phosphor paste) can be adjusted by adding an organic solvent. As the organic solvent, a known organic solvent that dissolves the resin may be used. As the additive, a flow control material composed of an inorganic filler such as glass particles or metal oxide particles or an organic component can be used.

The phosphor resin composition is produced by mixing and kneading a phosphor powder, a resin, and, if necessary, an organic solvent and/or an additive. Mixing and kneading may be performed by using a known means, for example, a three-roll kneader, a single-screw or twin-screw kneader, a self-rotating and revolving stirring and defoaming device, and/or a planetary mill. The obtained phosphor resin composition is used as a phosphor paste for producing a phosphor.

### «4. Phosphor»

The phosphor of the present embodiment is a shaped body of the phosphor resin composition described above. The shaped body is a concept including a coating film and/or a filler obtained from the composition. That is, a phosphor resin composition (phosphor paste) is applied, filled, or shaped, and further dried and/or cured as necessary to prepare a phosphor. The phosphor has phosphor powder (particles) dispersed in a resin serving as a matrix.

### «5. Light-Emitting Element»

The light-emitting element of the present embodiment includes the above-described phosphor and an excitation source. The excitation source serves to emit light towards the phosphor to excite the phosphor. As the excitation source, an LED having a central wavelength of 250 nm or more and 510 nm or less, particularly, a blue LED having a central wavelength of 450 nm or more and 460 nm or less is suitable. The arrangement of the phosphor and the excitation source is not limited as long as the light from the excitation source is incident on the phosphor. However, it is preferable to place the phosphor directly above the excitation source. As a result, the phosphor can more efficiently absorb light emitted from the excitation source and can convert the color. For example, in the case where the light-emitting element is applied to a micro LED display, it is preferable that an LED serving as an excitation source is disposed in a lower portion in each package rib of the display and a phosphor is disposed in an upper portion thereof. As a member of the light-emitting element, quantum dots may be used instead of the phosphor, but the quantum dots often contain environmentally regulated substances. Further, since quantum dots are poor in durability, phosphors are more advantageous.

### «6. Light-Emitting Device»

The light-emitting device of the present embodiment includes the above-described light-emitting element. The light-emitting device is not particularly limited as long as it includes a phosphor light-emitting element. Examples of the light-emitting device include display devices and lighting. The display devices include, but are not limited to, micro LED displays and mini LED displays.

A micro LED display is particularly suitable as the light-emitting device of the present embodiment. A micro LED display, in which the thickness of a phosphor layer (phosphor) is as small as several ten micrometers to several hundred micrometers, is required to sufficiently absorb emitted light (excitation light) to obtain excellent emission color. In the light-emitting element of the present embodiment, the phosphor included therein has a high absorbance, resulting in excellent emission color. Therefore, the above-described requirements are met.

### EXAMPLES

The present invention will be described in more detail with reference to the following Examples. However, the present invention is not limited to the following Examples.

### (1) Preparation of Phosphor Powder

### Examples 1 to 8 and Comparative Examples 1 to 3

Barium sulfide (BaS), strontium sulfide (SrS), europium sulfide (EuS), and gallium sulfide (Ga₂S₃) were prepared, and were weighed so that an amount of Eu (Eu/(Ba+Sr+Eu), which corresponds to a light emission center element concentration ratio), an amount of Ba (Ba/(Ba+Sr)), and an amount of Ga (Ga/(Eu+Ba+Sr)) were as shown in Table 1 below in terms of molar ratio. Next, the obtained weighed materials were mixed using zirconia balls having a diameter of 3 mm for 100 minutes by using a paint shaker to obtain a raw material mixture. Thereafter, the obtained raw material mixture was sintered in a hydrogen sulfide (H₂S) atmosphere to obtain a sintered product. At this time, sintering was performed under the conditions (temperature rising rate, sintering temperature and sintering time) shown in Table 1 below.

50 g of the obtained sintered product and 50 g of ethanol were placed into a 500 mL alumina pot to obtain a mixed liquid having a solid content concentration of 50% by mass. Then, a wet crushing treatment using a ball mill was performed to obtain phosphor powder as a crushed product. In the crushing treatment, 300 g of zirconia balls with a diameter of 7 mm and 400 g of zirconia balls with a diameter of 3 mm were used. The rotation speed of the ball mill pot was 300 rpm, and the treatment time by the ball mill was 4 hours.

The obtained phosphor powder (crushed product) was dissolved in an acid and subjected to composition analysis by ICP-OES, and it was confirmed that the composition of the phosphor powder was substantially the same as the charged composition.

### (2) Evaluation

The phosphor powders obtained in Examples 1 to 8 and Comparative Examples 1 to 3 were evaluated for various properties as follows.

### <Fluorescence Spectra and Excitation Spectra>

Fluorescence spectra and excitation spectra of the phosphor powders (samples) obtained in Examples and Comparative Examples were determined as follows. Specifically, measurements and analyses were performed using a spectrofluorometer FP-8500 and an integrating sphere unit ISF-834 (manufactured by JASCO Corporation) according to a solid quantum efficiency calculation program. The spectrofluorometer was calibrated using a sub-standard light source and rhodamine B. Fluorescence spectra and excitation spectra were obtained under the conditions of a band width of 5 nm on both an excitation side and a fluorescence side, a scanning rate of 500 nm/min, a data acquisition interval of 0.2 nm, and a response of 1 second. In the measurement of the fluorescence spectra, the wavelength of the excitation light was fixed at 450 nm, the fluorescence wavelength was scanned, and the wavelength (maximum fluorescence wavelength λmax) that provides the maximum (the largest) fluorescence intensity on the spectrum was obtained. When excitation spectra were measured, the excitation light wavelength was scanned to obtain a spectrum showing the fluorescence intensity at the maximum fluorescence wavelength λmax.

Next, in each of the obtained excitation spectra, fluorescence intensity (I₂₅₀) with respect to excitation light having a wavelength of 250 nm, fluorescence intensity (I₄₅₀) with respect to excitation light having a wavelength of 450 nm, fluorescence intensity (I₅₀₀) with respect to excitation light having a wavelength of 500 nm, maximum fluorescence intensity (I₃₃₀₋₃₆₀) with respect to excitation light having a wavelength of 330 nm or more and 360 nm or less, and maximum fluorescence intensity (I₃₈₀₋₄₂₀) with respect to excitation light having a wavelength of 380 nm or more and 420 nm or less were obtained, and the fluorescence intensity ratios (I₄₅₀/I₃₈₀₋₄₂₀, I₄₅₀/I₃₃₀₋₃₆₀, I₄₅₀/I₅₀₀, and I₃₈₀₋₄₂₀/I₂₅₀) were calculated.

### <Absorbance>

The absorbance (Abs.) was measured as follows using the phosphor powder (sample) as a sample for absorbance measurement. Specifically, measurements and analyses were performed using a spectrofluorometer FP-8500 and an integrating sphere unit ISF-834 (manufactured by JASCO Corporation) according to a solid quantum efficiency calculation program. The spectrofluorometer was calibrated using a sub-standard light source and rhodamine B. The following is a calculation formula of the absorbance of the phosphor powder (sample) when the excitation light is 450 nm under the conditions of a bandwidth of 5 nm on both the excitation side and the fluorescence side, a scanning rate of 500 nm/min, a data acquisition interval of 0.2 nm, and a response of 1 second. This calculation formula conforms to the description of the instruction manual of the FWSQ-6-17 (32) solid quantum efficiency calculation program made by JASCO Corporation.

P1(λ) and P2(λ) are a standard white plate spectrum and a sample spectrum, respectively. The area L1 under the spectrum P1(λ) between the excitation wavelengths ranging from 433 nm to 472 nm is determined as an excitation intensity (refer to equation (i) below). The area L2 under the spectrum P2(λ) between the excitation wavelengths ranging from 433 nm to 472 nm is determined as a sample scattering intensity (refer to equation (ii) below).

$$\begin{matrix}[ Formula 1 ] & \\ {L}_{1} = {\int }_{433}^{472} {P}_{1} ( λ ) d λ & ( i )\end{matrix}$$

$$\begin{matrix} & \\ {L}_{2} = {\int }_{433}^{472} {P}_{2} ( λ ) d λ & ( ii )\end{matrix}$$

The absorbance (Abs.) is a ratio of incident light corresponding to a decrease of excitation light by the sample, and is calculated according to the following equation (iii).

$$\begin{matrix}[ Formula 2 ] & \\ Abs = \frac{{L}_{1} - {L}_{2}}{{L}_{1}} & ( iii )\end{matrix}$$

### (3) Evaluation Results

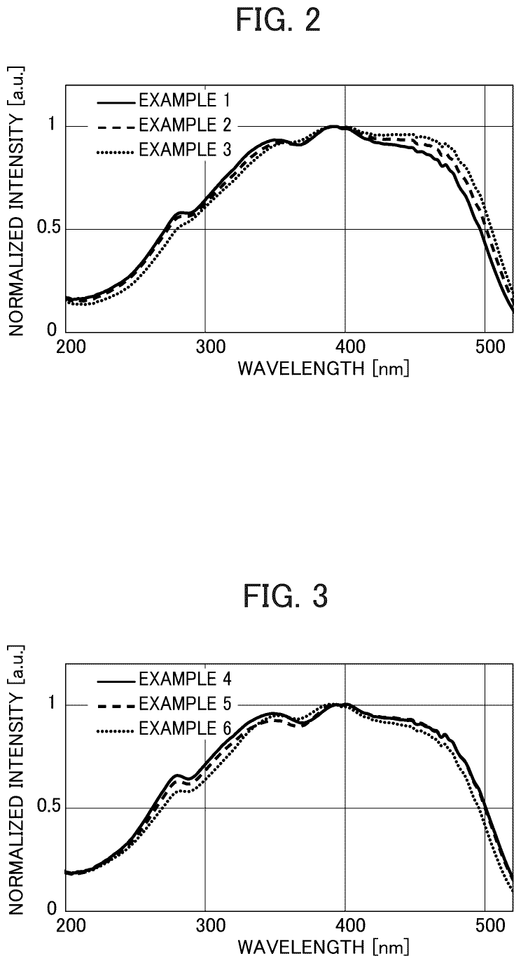

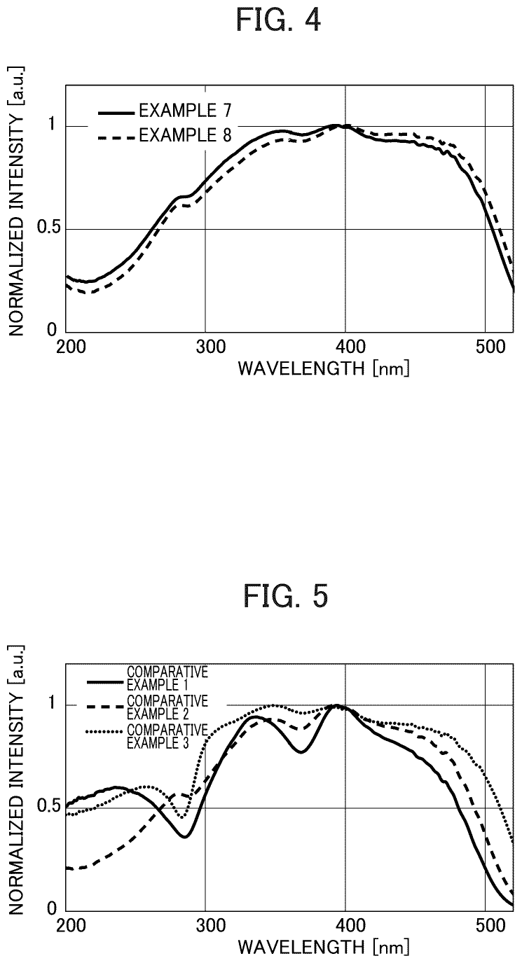

For Examples 1 to 8 and Comparative Examples 1 to 3, the fluorescence intensity ratios (I₄₅₀/I₃₈₀₋₄₂₀, I₄₅₀/I₃₃₀₋₃₆₀, I₄₅₀/I₅₀₀, and I₃₈₀₋₄₂₀/I₂₅₀) and the absorbance (Abs.) are shown together with the production conditions (Eu amount, temperature rising rate, sintering temperature, etc.) of the phosphor powder. Excitation spectra of Examples 1 to 8 and Comparative Examples 1 to 3 are shown in FIGS. 2 to 5.

In Examples 1 to 8, the Eu amount was as large as 0.08 or more and 0.30 or less, and the samples were produced by sintering at a relatively high temperature (1100° C.). In addition, the samples of the Examples except for Example 7 were produced at a relatively low temperature rising rate (0.3° C./min). In these samples, since the fluorescence intensity ratio (I₄₅₀/I₃₈₀₋₄₂₀) was 0.88 or more, the fluorescence intensity ratio (I₄₅₀/I₃₃₀₋₃₆₀) was 0.93 or more, the fluorescence intensity ratio (I₄₅₀/I₅₀₀) was 1.4 or more and 2.2 or less, and the fluorescence intensity ratio (I₃₈₀₋₄₂₀/I₂₅₀) was 2.7 or more, the absorbance was as high as 69% or more.

Contrary to the above, in Comparative Examples 1 and 2, the samples were produced with a small Eu amount as low as 0.01 or more and 0.07 or less, and a large temperature rising rate of 5° C./min. In these samples, since I₄₅₀/I₃₈₀₋₄₂₀ was as low as 0.86 or less, I₄₅₀/I₃₃₀₋₃₆₀ was as low as 0.92 or less, I₄₅₀/I₅₀₀ was less than 1.4 or greater than 2.2, and I₃₈₀₋₄₂₀/I₂₅₀ was as low as 2.6 or less, the absorbance was correspondingly as low as 61% or less.

The sample of Comparative Example 3 was produced by sintering at a relatively low temperature (850° C.), though the amount of Eu was as large as 0.13. In this sample, I₄₅₀/I₃₈₀₋₄₂₀ was as low as 0.87, I₄₅₀/I₃₃₀₋₃₆₀ was as low as 0.90, I₄₅₀/I₅₀₀ was as low as 1.37, and I₃₈₀₋₄₂₀/I₂₅₀ was as low as 1.7. Accordingly, the absorbance was as low as 64%.

From the above results, it can be seen that according to the present embodiment, a phosphor powder exhibiting a high absorbance to blue light is provided.

TABLE 1
Production conditions of phosphor powder and evaluation results

| | | | | | | | | | | Compar- | Compar- | Compar- |
|---|---|---|---|---|---|---|---|---|---|---|---|---|
| | | Exam- | Exam- | Exam- | Exam- | Exam- | Exam- | Exam- | Exam- | ative | ative | ative |
| | | ple 1 | ple 2 | ple 3 | ple 4 | ple 5 | ple 6 | ple 7 | ple 8 | Example 1 | Example 2 | Example 3 |
| Composition | Eu amount | 0.13 | 0.20 | 0.30 | 0.13 | 0.13 | 0.13 | 0.13 | 0.08 | 0.01 | 0.07 | 0.13 |
| | Eu/(Ba + Sr + Eu) | | | | | | | | | | | |
| | Ba amount | 0.25 | 0.25 | 0.25 | 0.00 | 0.10 | 0.30 | 0.00 | 0.00 | 0.25 | 0.25 | 0.00 |
| | Ba/(Ba + Sr) | | | | | | | | | | | |
| | Ga amount | 2.1 | 2.3 | 2.1 | 2.1 | 2.1 | 2.1 | 1.9 | 2.3 | 2.1 | 2.1 | 2.1 |
| | Ga/(Eu + Ba + Sr) | | | | | | | | | | | |
| Sintering | Temperature | 0.3 | 0.3 | 0.3 | 0.3 | 0.3 | 0.3 | 5 | 0.3 | 5 | 5 | 5 |
| conditions | rising rate | | | | | | | | | | | |
| | (° C./min) | | | | | | | | | | | |
| | Sintering | 1100 | 1100 | 1100 | 1100 | 1100 | 1100 | 1100 | 1100 | 1100 | 1100 | 850 |
| | temperature | | | | | | | | | | | |
| | (° C.) | | | | | | | | | | | |
| | Sintering | 3 days | 3 days | 3 days | 3 days | 3 days | 3 days | 3 days | 3 days | 3 days | 4 hrs | 4 hrs |
| | retention | | | | | | | | | | | |
| | time | | | | | | | | | | | |
| Fluorescent | I₄₅₀/I₃₈₀₋₄₂₀ | 0.89 | 0.92 | 0.95 | 0.91 | 0.91 | 0.88 | 0.91 | 0.95 | 0.76 | 0.86 | 0.87 |
| intensity | I₄₅₀/I₃₃₀₋₃₆₀ | 0.95 | 1.0 | 1.0 | 1.0 | 1.0 | 0.93 | 0.94 | 1.0 | 0.81 | 0.92 | 0.90 |
| ratio | I₄₅₀/I₅₀₀ | 2.0 | 1.8 | 1.6 | 1.7 | 1.8 | 2.1 | 1.6 | 1.4 | 3.6 | 2.3 | 1.37 |
| | I₃₈₀₋₄₂₀/I₂₅₀ | 3.3 | 3.4 | 4.0 | 2.7 | 2.9 | 3.0 | 2.7 | 3.0 | 1.7 | 2.6 | 1.7 |
| | Abs. (%) | 69 | 72 | 78 | 72 | 71 | 69 | 70 | 73 | 39 | 61 | 64 |

1. A phosphor powder having a ratio (I₄₅₀/I₃₈₀₋₄₂₀) of fluorescence intensity (I₄₅₀) with respect to excitation light having a wavelength of 450 nm and maximum fluorescence intensity (I₃₈₀₋₄₂₀) with respect to excitation light having a wavelength of 380 nm or more and 420 nm or less of 0.88 or more,
in an excitation spectrum showing fluorescence intensity of a maximum fluorescence wavelength λmax, provided that the maximum fluorescence wavelength λmax is a fluorescence wavelength that provides maximum fluorescence intensity with respect to an excitation light having a wavelength of 450 nm.

2. A phosphor powder having a ratio (I₄₅₀/I₃₃₀₋₃₆₀) of fluorescence intensity (I₄₅₀) with respect to excitation light having a wavelength of 450 nm and maximum fluorescence intensity (I₃₃₀₋₃₆₀) with respect to excitation light having a wavelength of 330 nm or more and 360 nm or less of 0.93 or more,
in an excitation spectrum showing fluorescence intensity of a maximum fluorescence wavelength λmax, provided that the maximum fluorescence wavelength λmax is a fluorescence wavelength that provides maximum fluorescence intensity with respect to an excitation light having a wavelength of 450 nm.

3. A phosphor powder having a ratio (I₄₅₀/I₅₀₀) of fluorescence intensity (I₄₅₀) with respect to excitation light having a wavelength of 450 nm and fluorescence intensity (I₅₀₀) with respect to excitation light having a wavelength of 500 nm of 1.4 or more and 2.2 or less,
in an excitation spectrum showing fluorescence intensity of a maximum fluorescence wavelength λmax, provided that the maximum fluorescence wavelength λmax is a fluorescence wavelength that provides maximum fluorescence intensity with respect to an excitation light having a wavelength of 450 nm.

4. A phosphor powder having a ratio (I₃₈₀₋₄₂₀/I₂₅₀) of maximum fluorescence intensity (I₃₈₀₋₄₂₀) with respect to excitation light having a wavelength of 380 nm or more and 420 nm or less and fluorescence intensity (I₂₅₀) with respect to excitation light having a wavelength of 250 nm of 2.7 or more,
in an excitation spectrum showing fluorescence intensity of a maximum fluorescence wavelength λmax, provided that the maximum fluorescence wavelength λmax is a fluorescence wavelength that provides maximum fluorescence intensity with respect to an excitation light having a wavelength of 450 nm.

5. The phosphor powder according to claim 1, wherein the phosphor powder comprises a crystal of a matrix compound and a light emission center element.

6. The phosphor powder according to claim 5, wherein a concentration ratio of the light emission center element is 8.0 mol % or more and 50 mol % or less.

7. The phosphor powder according to claim 5, wherein the matrix compound comprises a sulfide-based phosphor.

8. The phosphor powder according to claim 5, wherein the matrix compound comprises gallium (Ga), sulfur (S), and at least one metal element selected from the group consisting of barium (Ba), strontium (Sr), and calcium (Ca).

9. The phosphor powder according to claim 5, wherein the matrix compound has a basic composition of (Ba,Sr)Ga₂S₄.

10. The phosphor powder according to claim 1, wherein the phosphor powder has a composition represented by (Ba,Sr)₁₋ₓGa₂S₄:Euₓ (where 0.08≤x≤0.50).

11. The phosphor powder according to claim 1, wherein the phosphor powder has an absorbance of 65% or more with respect to excitation light having a wavelength of 450 nm.

12. A phosphor resin composition comprising the phosphor powder according to claim 1, and a resin.

13. A phosphor comprising the phosphor resin composition according to claim 12.

14. A light-emitting element comprising the phosphor according to claim 13 and an excitation source.

15. A light-emitting device comprising the light-emitting element according to claim 14.
